(19) United States
(12) Patent Application Publication
(10) Pub. No.: US 2009/0002199 A1
(43) Pub. Date: Jan. 1, 2009

(54) Piezoelectric sensing as user input means

(75) Inventors: Juhani Lainonen, Riihiniityntie (FI); Marko Karhiniemi, Kilonpuisto (FI)

Correspondence Address: WARE FRESSOLA VAN DER SLUYS & ADOLPHSON, LLP, BRADFORD GREEN, BUILDING 5, 755 MAIN STREET, P O BOX 224, MONROE, CT, 06468, US

(73) Assignee: Nokia Corporation

(21) Appl. No.: 11/879,739

(22) Filed: Jul. 17, 2007

Related U.S. Application Data
(60) Provisional application No. 60/937,520, filed on Jun. 28, 2007.

(51) Int. Cl. H03M 11/00

(52) U.S. Cl. 341/20

(57) ABSTRACT

The specification and drawings present a new apparatus and method for providing and using piezoelectric sensing with force detection as user input means possibly in combination with touch sensing methods in a user interface module (e.g., touch pad, keyboard, keymat, touch-screen, etc.).

### PRIORITY AND CROSS-REFERENCE TO RELATED APPLICATION

This application claims priority from U.S. Patent Application Ser. No. 60/937,520, filed on Jun. 28, 2007.

### TECHNICAL FIELD

The present invention relates generally to electronic devices and, more specifically, to using piezoelectric sensing with force detection as user input means in user interface modules.

### BACKGROUND ART

User input means (such as a user interface) of an electronic device can be implemented in various ways. Touch pads, keyboards, keymats, touch-screen, etc. are well known user interfaces especially for portable devices as laptop computers and mobile telephones. A touch pad is an input device which typically includes a sensor and an associate circuitry. When a user moves a stylus or a finger to touch (or to put in a close proximity) the touch pad, that contact effects the sensor and is detected by the circuitry. There are various mechanisms for detecting the point of contact on the touch pad.

One approach for detecting a user input is generating an electrical field and detecting a deformation of the electric field by a user. The electric field can be generated, for instance, within the area of a touch-screen. The disturbance of that field caused by the object may then depend on the position at which the touch-screen is touched by the object (e.g., stylus, finger of the user, etc.). For generating and monitoring such electrical field, different sensor technologies can be employed. One option is to use a capacitive detection. Capacitive touch sensing technology is used currently in multiple mobile devices for example in various MP3 players and mobile phones.

Among multiple capacitive touch pad principles, a capacitive detector can comprise at least one conductive plate or electrode, which forms a capacitance with at least one another conductive plate or electrode. In a capacitive detector, an electric filed is set between these electrodes. Then the disturbances of the electric field induced, for example, by a user finger (e.g., by touching, which can act as grounding or disturbing element) can be detected by monitoring the capacitance value between these two electrodes (e.g., using the measurement circuitry). Thus capacitance values (i.e., changes in the disturbed electric field) can be used for detecting whether there is some object in close proximity of the detector or not, and at which position. This principle can be used in a matrix type grid sensor arrangement with rx and tx electrodes separated by a gap, wherein the object (e.g., a finger) causes disturbances in coupling the signal which is detected by the measurement circuitry, as disclosed, for example, in U.S. Pat. No. 6,452,514 “Capacitive Sensor and Array” by H. Philipp.

There are other multiple alternative methods and variations in the measurement technique in using the capacitance measurement for detection. For example, principles, disclosed in US patent U.S. Pat. No. 6,466,036 “Charge Transfer Capacitance Measurement Circuit” by H. Philipp, can be applied to a semi-conductive plate (or possibly to a conductive plate) to measure the location of the finger as well, using the following. Charge pulses can be injected from a number of electrodes placed around the touch plane (e.g., semi-conducting touch plane) at least three preferably at least four electrodes. There can be more electrodes for increased accuracy and performance. These charge pulses generate electric field around the semi-conductive plane and the finger absorbs energy of some of the pulses (capacitive connection to the plane). The injected charges are collected and counted. The sensing electrodes from the corners of the touch plane have resistance values to the point which forms the capacitance connection to the finger, i.e., changes in the resistance can be detected as changes in an electric current (resistive-capacitive detection). Relative resistance values determine the distances from the corners indicating coordinate values.

However, capacitive sensing measurement cannot distinguish sometimes between false and correct capacitive signals, which may cause false activations or interference. Examples of these situations could be hand shadow capacitance, e.g., if other fingers (the same or another hand) are is a close proximity of the sensor, or metallic objects at the sensor proximity area. These factors can cause inaccurate sensor behavior. Therefore, the capacitive touch pad can operate very well as a touch pad after an appropriate selection but the actual selection is usually done with separate keys using other methods. In principle, the activation in mobile devices could be done with the same touch pad, however, it is difficult to do with a capacitive sensing based touch pad, because the activation threshold varies according to conditions.

Furthermore, the capacitive sensing technology can detect force as the capacitive signal level increases due to more firm press (e.g., finger squeezes). However, this detection may be not accurate because the finger size varies, and there could be interfering capacitive signals in the proximity area as mentioned herein. Alternative approaches are also unreliable and limited in accuracy and linearity of the response as a function of applied force. For example, a resistive touch pad or touch screen can detect a discrete force when the two layers bend and contact each other galvanically. Also using domes with switches (activated by pressing) beneath the pad can be used for a force detection.

Piezoelectric transducers are used primarily in touch-type controls (user interfaces) for providing a feedback signal (tactile signal, vibration signal, etc.). For example, in U.S. Pat. No. 6,757,002 “Track Pad Pointing Device with Areas of Specialized Function” by G. Oross et al., a vibration source includes a piezoelectric material activated in a switch configuration when a finger in a special touch sensing area closes the switch causing a vibration to occur adjacent to the finger within the activated special touch sensing area. In another example, U.S. Pat. No. 7,148,875 “Haptic Feddback fro Touchpad and Other Touch Controls” by L. Rosenberg et al., a piezoelectric actuator provides a force on the touchpad when an electrical signal is applied to the actuator (typically, a piezoelectric actuator includes two layers which can move relative to each other when a current is applied to the actuator: the grounded portion of the actuator remains stationary with respect to the surrounding housing while the moving portion of the actuator and the touchpad move with respect to the housing).

### DISCLOSURE OF THE INVENTION

According to a first aspect of the invention, an apparatus, comprises: a user interface layer comprising a touch surface; and a piezoelectric layer, configured to provide one or more levels of a force detection signal in response to an object touching the touch surface with one or more levels of a pressing force for applying a mechanical stress to the piezoelectric layer, wherein the one or more levels of the force detection signal correspond to the one or more levels of the pressing force and are for communicating one or more predetermined commands.

According further to the first aspect of the invention, the level of the force detection signal may be proportional to the level of a predetermined force. Further, the apparatus may be configured to use the one or more predetermined commands for continuously scrolling information using varying the force detection signal as a function of the pressing force.

Further according to the first aspect of the invention, the apparatus may further comprise: a first electrode layer; and a second electrode layer, wherein the piezoelectric layer is between the first electrode layer and the second electrode layer for providing the force detection signal. Further, the first electrode layer may be a touch sensor/electrode layer, configured to provide a sensor signal as a function of a location of an object on or near the non-flat touch surface when the object touches or in a close proximity of the touch surface, and wherein the second electrode layer may be a reference potential layer or a ground electrode layer.

Still further according to the first aspect of the invention, the apparatus may further comprise: a touch sensor layer, configured to provide a sensor signal as a function of a location of an object on or near the touch surface when the object touches or is in a close proximity to the touch surface, wherein the force detection signal and the sensor signal are used in combination to provide control information. Further, the user interface layer, the touch sensor layer and the piezoelectric layer may be parts of a user interface module. Still further, the touch sensor layer may comprise a touch sensor for providing the sensor signal and the touch sensor may be a capacitive sensor, a resistive-capacitive sensor or a resistive sensor. Yet still further, the touch sensor layer may be an impedance sensor conductive layer of a rectangular shape with four contact points at corners of the touch sensor.

According further to the first aspect of the invention, the piezoelectric layer may be made of a polymer or a polymer and ceramic mixture.

Yet still further according to the first aspect of the invention, the apparatus may further comprise: a semi-soft polymer layer configured to provide a pre-selected bending level of the piezoelectric layer.

According still further to the first aspect of the invention, the apparatus may be an electronic device configured for wireless communications.

According to a second aspect of the invention, a user interface module, comprises: a user interface layer comprising a touch surface; and a piezoelectric layer, configured to provide one or more levels of a force detection signal in response to an object touching the touch surface with one or more levels of a pressing force for applying a mechanical stress to the piezoelectric layer, wherein the one or more levels of the force detection signal correspond to the one or more levels of the pressing force and are for communicating one or more predetermined commands to an electronic device.

According further to the second aspect of the invention, the user interface module may be a part of the electronic device.

Further according to the second aspect of the invention, the user interface module may be connected to the electronic device by an electrical or wireless connection.

Still further according to the second aspect of the invention, the level of the force detection signal may be proportional to the level of a predetermined force.

According further to the second aspect of the invention, the user interface module may be configured to use the one or more predetermined commands for continuously scrolling information using varying the force detection signal as a function of the pressing force.

According still further to the second aspect of the invention, the user interface module may further comprise: a first electrode layer; and a second electrode layer, wherein the piezoelectric layer is between the first electrode layer and the second electrode layer for providing the force detection signal.

According further still to the second aspect of the invention, the first electrode layer may be a touch sensor/electrode layer, configured to provide a sensor signal as a function of a location of an object on or near the non-flat touch surface when the object touches or in a close proximity of the touch surface, and wherein the second electrode layer may be a reference potential layer or a ground electrode layer.

According yet further still to the second aspect of the invention, the user interface module may further comprises: a touch sensor layer, configured to provide a sensor signal as a function of a location of an object on or near the touch surface when the object touches or is in a close proximity to the touch surface, wherein the force detection signal and the sensor signal are used in combination to provide control information. Further, the user interface layer, the touch sensor layer and the piezoelectric layer may be parts of a user interface module. Still further, the touch sensor layer may comprise a touch sensor for providing the sensor signal and the touch sensor may be a capacitive sensor, a resistive-capacitive sensor or a resistive sensor. Yet still further, the touch sensor layer may be an impedance sensor conductive layer of a rectangular shape with four contact points at corners of the touch sensor.

Yet still further according to the second aspect of the invention, the piezoelectric layer may be made of a polymer or a polymer and ceramic mixture.

Still yet further according to the second aspect of the invention, the user interface module may further comprise: a semi-soft polymer layer configured to provide a pre-selected bending level of the piezoelectric layer.

According to a third aspect of the invention, a method, comprises: pressing a touch surface of a user interface layer by an object with a pressing force for applying a mechanical stress to a piezoelectric layer; and providing a force detection signal in response to the object touching the touch surface with the pressing force by the piezoelectric layer, wherein the piezoelectric layer is configured to provide one or more levels of the force detection signal in response to the object touching the touch surface with one or more levels of the pressing force, wherein the one or more levels of the force detection signal correspond to the one or more levels of the pressing force and are for communicating at least two predetermined commands to an electronic device.

According further to the third aspect of the invention, the pressing may be for providing the force detection signal to wake up the electronic device.

Further according to the third aspect of the invention, the method may further comprise: further touching a touch surface of the user interface layer by the object; and providing by a touch sensor layer a sensor signal as a function of a location of the object on the touch surface in response to the further touching, wherein the force detection signal and the sensor signal are used in combination to provide control information to an electronic device. Further, the user interface layer, the touch sensor layer and the piezoelectric layer may be parts of a user interface module. Still further, the touch sensor layer may comprise a touch sensor for providing the sensor signal and the touch sensor may be a capacitive sensor, a resistive-capacitive sensor or a resistive sensor. Yet still further, the touch sensor layer may be an impedance sensor conductive layer of a rectangular shape with four contact points at corners of the touch sensor.

Still further according to the third aspect of the invention, the level of the force detection signal may be proportional to the level of a predetermined force.

According further to the third aspect of the invention, the one or more predetermined commands may be for continuously scrolling information using varying the force detection signal as a function of the pressing force.

According still further to the third aspect of the invention, the piezoelectric layer may be made of a polymer or a polymer and ceramic mixture.

### BRIEF DESCRIPTION OF THE DRAWINGS

For a better understanding of the nature and objects of the present invention, reference is made to the following detailed description taken in conjunction with the following drawings, in which:

FIG. 1 is a schematic representation of piezoelectric sensing with force detection possibly combined with touch sensing using a planar layer implementation, according to an embodiment of the present invention;

FIG. 2 is a schematic representation of a capacitive touch sensing using impedance measurement principle utilizing resistive-capacitive detection which can be used in combination with piezoelectric sensing;

FIG. 3 is a schematic representation of piezoelectric sensing with force detection possibly combined with touch sensing using a curved shape layer implementation, according to an embodiment of the present invention;

FIG. 4 is a schematic representation of piezoelectric sensing with force detection combined with touch sensing implemented in a separate layer using a planar layer implementation, according to an embodiment of the present invention;

FIG. 5 is a graph demonstrating a linear dependence of a voltage generated by a piezoelectric layer vs. applied force, according to an embodiment of the present invention;

FIG. 6 is a flow chart demonstrating piezoelectric sensing with force detection combined with touch sensing, wherein piezoelectric sensing is used for selecting a task, according to an embodiment of the present invention; and

FIG. 7 is a flow chart demonstrating piezoelectric sensing with force detection possibly combined with touch sensing, wherein piezoelectric sensing is used for scrolling information, according to an embodiment of the present invention.

### MODES FOR CARRYING OUT THE INVENTION

A new apparatus and method are presented for providing and using piezoelectric sensing with force detection as user input means possibly in combination with touch sensing methods in a user interface module (e.g., touch pad, keyboard, keymat, touch-screen, etc.).

According to an embodiment of the present invention, a piezoelectric layer can be configured to provide a force detection signal in response to an object (e.g., finger, stylus, etc.) touching or pressing a touch surface (or a user interface layer) of the user interface module with a pressing force for applying a mechanical stress to the piezoelectric layer causing strain bending in the piezoelectric layer material and thus generating an electric voltage (i.e., the force detection signal), wherein the force detection signal is a function, e.g., a linear function, of the piezoelectric layer force. The force detection signal can have a predetermined number of levels (one or more) as a function of corresponding levels of applied force, e.g., for providing predetermined commands (e.g., selections, control information, etc.) to an electronic device used with the user interface module. Moreover, this force detection signal can vary continuously as a function of said force, e.g., for providing scrolling of information in said electronic device (e.g., on a display).

It is noted that the electric device can comprise the user interface module or the user interface module can be used remotely using an electrical or a wireless connection. It is further noted that the piezoelectric layer can be made of a polymer, a polymer and ceramic mixture or similar materials. An additional semi-soft polymer layer can be used to provide a pre-selected bending level of said piezoelectric layer.

According to a further embodiment of the present invention, the force detection can be used in combination with a touch sensor layer comprising touch sensor/sensors (e.g., a capacitive sensor, a resistive-capacitive sensor, a resistive sensor, etc.) and configured to provide a sensor signal as a function of a location of an object on or near said touch surface when said object touches or is in a close proximity to said touch surface. Then said force detection signal and said sensor signal can be used in combination to provide control information to the electronic device. Combination of these two technologies (the force detection using piezoelectric sensing and touch sensing) can be used to enhance input devices for mobile, wireless and other devices and applications.

A few scenarios for using new or enhanced input devices, according to embodiments of the present invention, are as follows.

For example, the force detection with piezoelectric sensing can be used to activate a selection in the electronic device when the finger is pressed firmly with the pressing force like in a normal key press on a touch surface (layer) of the user interface module. After the selection is made, the same area (the touch surface of the user interface module) can be used as a touch pad by pressing more gently, wherein coordinates (location of the finger) is determined by the touch sensing (e.g., capacitive measurement).

In another scenario, the force detection using piezoelectric sensing can be used to generate an activation pulse to wake up the device, which is a notable advantage because the measurement circuitry do not have to be in an active measurement state all the time.

Moreover, according to another embodiment, the initial activation (selection) can be performed using touch sensing (e.g., capacitive, resistive, etc.) or another conventional sensing using for example dome technology, and then the force detection with piezoelectric sensing can be used for providing the force detection signal proportional to the applied force as a scrolling mechanism of the information in the electronic device through said user interface module. It is also noted that the initial activation (selection) can be performed using the piezoelectric sensing as well by using a signal of a predetermined pressing pattern (e.g., by pressing the touch surface two or more times in sequence).

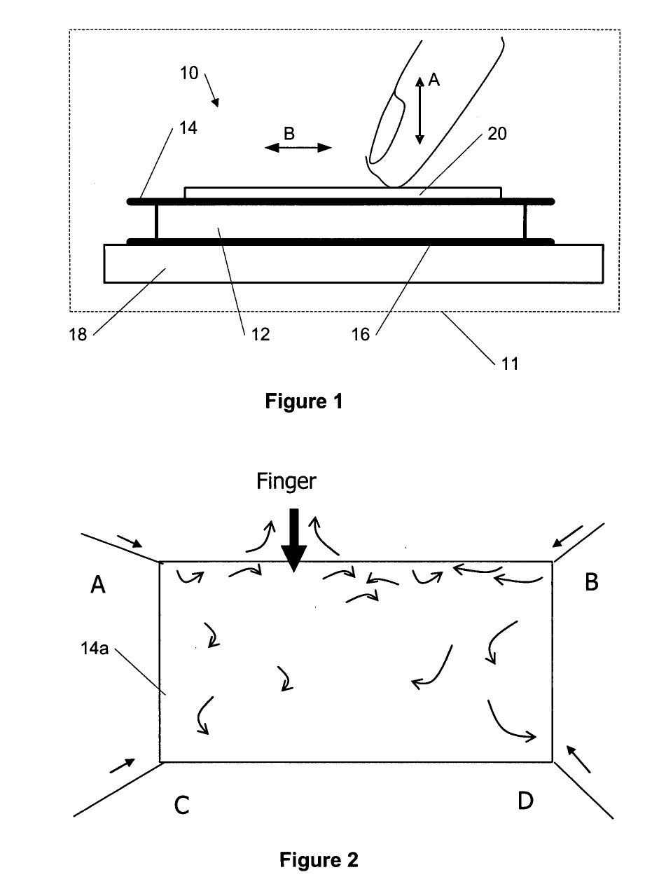

FIGS. 1-7 provide examples for implementing various embodiments of the present invention.

FIG. 1 shows one example among others of the user interface module 10 (e.g., touch pads, keyboards, keymats, touch-screens, etc.) comprised in an electronic device 11 with a piezoelectric layer 12 for providing force detection sensing, possibly combined with touch sensing using a planar layer implementation, according to an embodiment of the present invention.

The piezoelectric layer 12 can be made of a polymer, a polymer and ceramic mixture, or similar materials. The piezoelectric layer 12 is placed between a first electrode (conductive) layer 14 and a second electrode conductive layer 16 (e.g., a reference potential layer or a ground electrode layer) for providing the force detection signal (i.e., a voltage generated between the electrodes layers 14 and 16) when a pressing force is applied in a direction A to a user interface layer 20 at any location as shown in FIG. 1 causing strain bending in the piezoelectric layer 12 and thus generating an electric voltage (i.e., a force detection signal), as described herein. Electrode (conductive) layers 14 and 16 are used for providing the force detection signal to an appropriate electronic circuitry (not shown in FIG. 1) for further processing and generating appropriate commands as known in the art. An additional semi-soft polymer layer 18 is used to provide a pre-selected bending level of said piezoelectric layer. The layer 20 can be a standard interface layer of a keymat, keypad, etc. with appropriate decorations. The layer 20 should be preferably made of an easily bendable (flexible) material, so the force provided by the object in the direction A can be effectively applied to the piezoelectric layer 12. The same can be applied to the electrodes conductive layers 14 and 16: they can be made, e.g., of a flexible conductive material. (e.g., metal tape, plastic foil with conductive indium tin oxide, graphite paper, etc.). It is further noticed that the layers 14 and 16 can be made of a semi-conducting material with a resistivity 500 Ohms/square to 50 k Ohms/square, conductive polymers, conductive inks, silver paint, ITO (indium tin oxide), ATO (antimony tin oxide), etc.

According to a further embodiment, the first electrode layer 14 shown in FIG. 1 can have a further function: it can provide touch sensing when, for example, the object touches on or near (for some capacitive sensing methods) the user interface layer 20 of the user interface module 10 and moves along its surface in a direction A as shown in FIG. 1.

There are multiple alternatives for the capacitive touch sensor layer depending on the measurement principle and measurement arrangement as briefly described in the Background section. For example, the capacitive touch sensor layer can be homogenous and semi-conductive with a resistivity, e.g., 500 Ohms/square to 50 kOhms/square or conducting using a principle outlined in the US patent U.S. Pat. No. 6,466,036“Charge Transfer Capacitance Measurement Circuit” by H. Philipp as illustrated in FIG. 2, showing one example among others for implementing a capacitive touch sensing using impedance measurement principle utilizing resistive-capacitive detection, which can be used in combination with the piezoelectric sensing.

In impedance measurement sensing technology as illustrated in FIG. 2, charges are injected at the same time (charge pulses) from the end-points A, B, C, and D to a rectangle shaped sensor 14a, which can be the electrode layer 14 (e.g., conductive or semi-conductive) shown in FIG. 1 (the sensor shape can be different than a rectangle shape depending on the implementation and design). Charges go to the locations A, B, C, D, and F (finger) depending on the impedance (resistivity on the sensor and resistive-capacitance connection to the finger). The charge distribution between A, B, C, D, F is measured and transformed to a signal level value, thus generating a sensor (touch) signal, as described herein (i.e., changes in the resistance can be detected as changes in an electric current).

Also other types of capacitive and resistive sensors can be utilized in the layer 14. The capacitive touch sensor layer can be a matrix type of grid, using a measurement principle outlined in the U.S. Pat. No. 6,452,514 “Capacitive Sensor and Array” by H. Philipp (in this method the sensor electrodes are preferably conductive but can be semi-conductive as well). It is further noted that combinations and variations in the measurement principles and arrangements are possible. Since the electric fields are different in different sensor arrangement and measurement principle, thus, the dielectric variations should be applicable and implemented depending on the measurement principle and arrangement. Moreover, in order to separate the touch sensor signal and the force detection signals, different signal modulation schemes can be used which are known to a person skilled in the art.

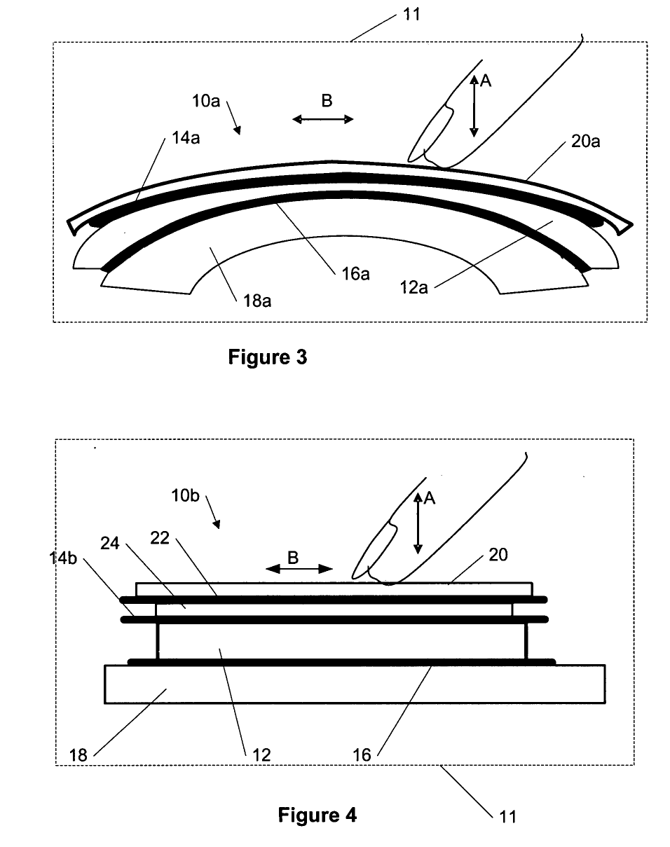

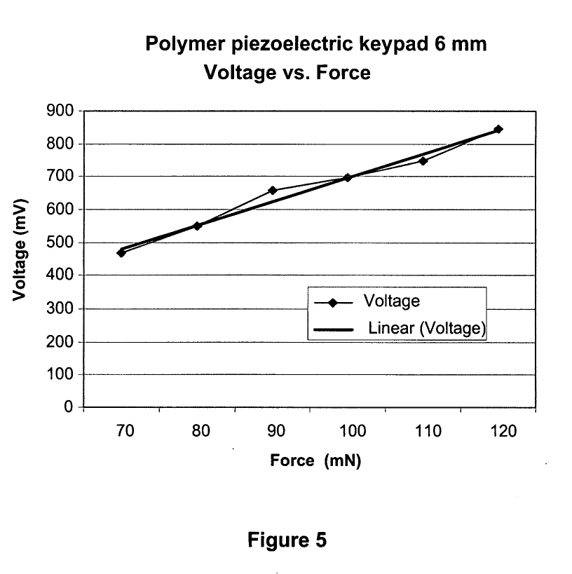

It is noted that the user interface module 10 shown in FIG. 1 can be a part of the electronic device 11 or the module 10 can be a separate unit (e.g., a remote control) from the electronic device 11. In the latter case, the module 10a can be connected to the electronic device 11 by an electrical or a wireless connection. The same is applied to the examples of FIGS. 3 and 4. The electronic device 11 can be, but is not limited to, a wireless portable device, a mobile communication device, a mobile phone, a computer, an electronic communication device, an electronic game device, a personal digital assistant device, etc. It is further noted that the associate electronic circuitry for the force detection sensing and the touch sensing is not shown in FIG. 1 and further in FIGS. 3 and 5 but it is well known to a person skilled in the art.

FIG. 3 shows yet another example among others of the user interface module 10a (e.g., touch pads, keyboards, keymats, touch-screens, etc.) comprised in an electronic device 11 with a piezoelectric layer 12a for providing force detection sensing possibly combined with touch sensing using a curved shape layer implementation, according to an embodiment of the present invention. Functionality of layers 12a, 14a, 16a, 18a and 20a is the same as of corresponding layers 12, 14, 16, 18 and 20 shown in FIG. 1. The difference with FIG. 1 is that the nature of used materials allows bending and different curved shapes including 3-dimensional surfaces as shown in FIG. 3. Theses curved surfaces can be used, e.g., in terminal covers.

FIG. 4 shows yet another example among others of the user interface module 10b (e.g., touch pads, keyboards, keymats, touch-screens, etc.) comprised in an electronic device 11 with a piezoelectric layer 12 for providing force detection sensing combined with touch sensing implemented in a separate layer 22 using a planar layer implementation, according to an embodiment of the present invention. In this example the touch sensor layer 22 is dedicated to providing a sensor signal such that the layer 14b serves only as a conducting electrode for providing the force detection signal generated by the piezoelectric layer 12, as described herein. Also an additional isolation layer 24 is used between layers 14b and 22. Other layers shown in FIG. 4 have the same function and construction as in FIG. 1.

FIG. 5 shows an example of a graph demonstrating a linear dependence of a voltage generated by a piezoelectric layer vs. applied force, according to an embodiment of the present invention. The keypad size is 6 mm square. The graph shown in FIG. 5 was generated using an object of a variable mass (but having the same shape and size) freely released from the same height of 5 mm from a piezoelectric element (made of a polymer-ceramic mixture) impacting the piezoelectric element with a pressing force proportional to the mass for applying the mechanical stress to the piezoelectric layer and thus generating the output voltage by this piezoletric element.

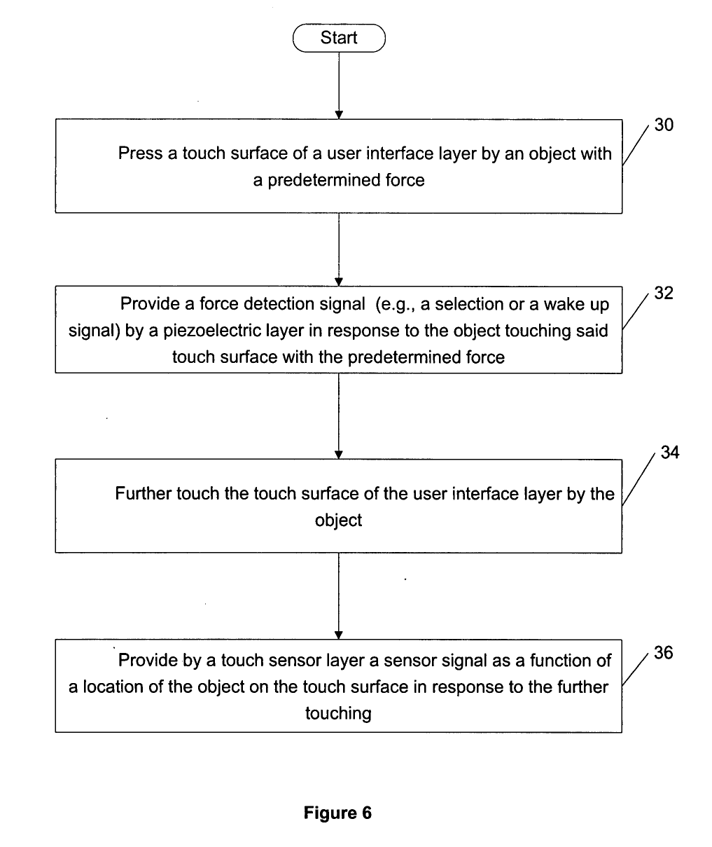

FIG. 6 shows a flow chart demonstrating piezoelectric sensing with force detection combined with touch sensing, wherein piezoelectric sensing is used for selecting a task, according to an embodiment of the present invention.

The flow chart of FIG. 6 only represents one possible scenario among others. It is noted that the order of steps shown in FIG. 6 is not absolutely required, so in principle, the various steps can be performed out of order. In a method according to the embodiments of the present invention, in a first step 30, an object (e.g., a finger or a stylus) presses a touch surface of the user interface layer (of the user interface module) with a pressing force. In a next step 32, a piezoelectric layer of the user interface module provide a force detection signal (e.g., a selection or a wake up signal) in response to the object touching said touch surface with the pressing force. In a next step 34, the object further touches the touch surface of the user interface layer (e.g., sliding the finger along the touch surface). In a next step 36, a touch sensor layer provides a sensor signal as a function of a location of the object on the touch surface in response to said further touching (e.g., to provide by the user interface module a series of commands or scrolling information data in the electronic device).

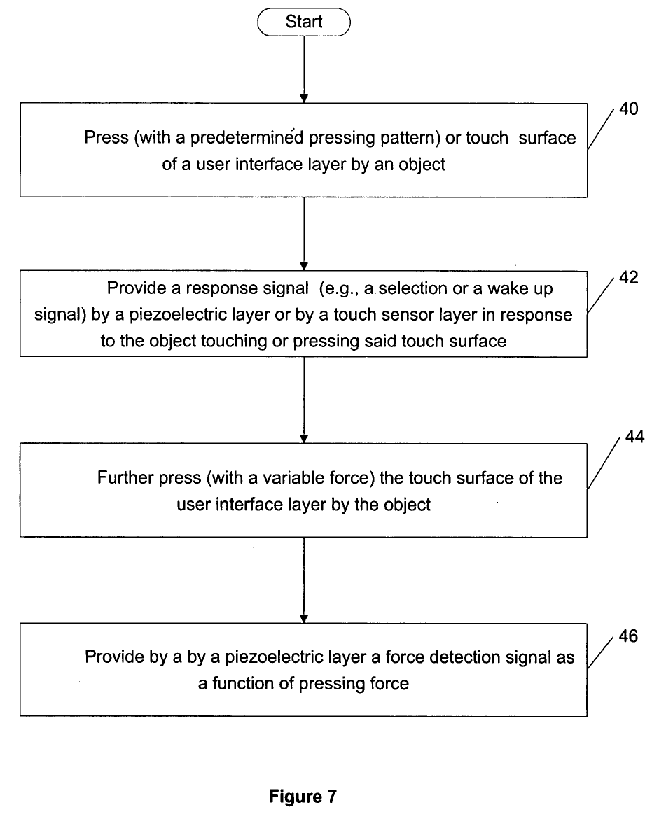

FIG. 7 shows a flow chart demonstrating piezoelectric sensing with force detection possibly combined with touch sensing, wherein piezoelectric sensing is used for scrolling information, according to an embodiment of the present invention.

The flow chart of FIG. 7 only represents one possible scenario among others. It is noted that the order of steps shown in FIG. 7 is not absolutely required, so in principle, the various steps can be performed out of order. In a method according to the embodiments of the present invention, in a first step 40, an object (e.g., a finger or a stylus) presses (with a predetermined pressing pattern) or touches a touch surface of the user interface layer (of the user interface module). In a next step 42, a piezoelectric layer or a touch sensor layer provides a response signal (e.g., a selection or a wake up signal) in response to the object touching or pressing said touch surface. In a next step 44, the object further presses (with a variable force) the touch surface of the user interface layer. In response, in a step 46, the piezoelectric layer provides a force detection signal as a function of pressing force (e.g., to provide by the user interface module a series of commands or scrolling information data in the electronic device).

It is noted that various embodiments of the present invention recited herein can be used separately, combined or selectively combined for specific applications.

It is to be understood that the above-described arrangements are only illustrative of the application of the principles of the present invention. Numerous modifications and alternative arrangements may be devised by those skilled in the art without departing from the scope of the present invention, and the appended claims are intended to cover such modifications and arrangements.

What is claimed is:

1. An apparatus, comprising:
a user interface layer comprising a touch surface; and
a piezoelectric layer, configured to provide one or more levels of a force detection signal in response to an object touching said touch surface with one or more levels of a pressing force for applying a mechanical stress to said piezoelectric layer, wherein said one or more levels of the force detection signal correspond to said one or more levels of said pressing force and are for communicating one or more predetermined commands.

2. The apparatus of claim 1, wherein the level of said force detection signal is proportional to said level of a predetermined force.

3. The apparatus of claim 2, wherein said apparatus is configured to use said one or more predetermined commands for continuously scrolling information using varying said force detection signal as a function of said pressing force.

4. The apparatus of claim 1, further comprising:
a first electrode layer; and
a second electrode layer,
wherein said piezoelectric layer is between said first electrode layer and said second electrode layer for providing said force detection signal.

5. The apparatus of claim 4, wherein said first electrode layer is a touch sensor/electrode layer, configured to provide a sensor signal as a function of a location of an object on or near said non-flat touch surface when said object touches or in a close proximity of said touch surface, and
wherein said second electrode layer is a reference potential layer or a ground electrode layer.

6. The apparatus of claim 1, further comprising:
a touch sensor layer, configured to provide a sensor signal as a function of a location of an object on or near said touch surface when said object touches or is in a close proximity to said touch surface,
wherein said force detection signal and said sensor signal are used in combination to provide control information.

7. The apparatus of claim 6, wherein said user interface layer, said touch sensor layer and said piezoelectric layer are parts of a user interface module.

8. The apparatus of claim 6, wherein said touch sensor layer comprises a touch sensor for providing said sensor signal and said touch sensor is a capacitive sensor, a resistive-capacitive sensor or a resistive sensor.

9. The apparatus of claim 6, wherein said touch sensor layer is an impedance sensor conductive layer of a rectangular shape with four contact points at corners of said touch sensor.

10. The apparatus of claim 1, wherein said piezoelectric layer is made of a polymer or a polymer and ceramic mixture.

11. The apparatus of claim 1, further comprising:
a semi-soft polymer layer configured to provide a pre-selected bending level of said piezoelectric layer.

12. The apparatus of claim 1, wherein said apparatus is an electronic device configured for wireless communications.

13. A user interface module, comprising:
a user interface layer comprising a touch surface; and
a piezoelectric layer, configured to provide one or more levels of a force detection signal in response to an object touching said touch surface with one or more levels of a pressing force for applying a mechanical stress to said piezoelectric layer, wherein said one or more levels of the force detection signal correspond to said one or more levels of said pressing force and are for communicating one or more predetermined commands to an electronic device.

14. The user interface module of claim 13, wherein said user interface module is a part of said electronic device.

15. The user interface module of claim 13, wherein said user interface module is connected to said electronic device by an electrical or wireless connection.

16. The user interface module of claim 13, wherein the level of said force detection signal is proportional to said level of a predetermined force.

17. The user interface module of claim 16, wherein said user interface module is configured to use said one or more predetermined commands for continuously scrolling information using varying said force detection signal as a function of said pressing force.

18. The user interface module of claim 13, further comprising:
a first electrode layer; and
a second electrode layer,
wherein said piezoelectric layer is between said first electrode layer and said second electrode layer for providing said force detection signal.

19. The user interface module of claim 13, wherein said first electrode layer is a touch sensor/electrode layer, configured to provide a sensor signal as a function of a location of an object on or near said non-flat touch surface when said object touches or in a close proximity of said touch surface, and
wherein said second electrode layer is a reference potential layer or a ground electrode layer.

20. The user interface module of claim 13, further comprising:
a touch sensor layer, configured to provide a sensor signal as a function of a location of an object on or near said touch surface when said object touches or is in a close proximity to said touch surface,
wherein said force detection signal and said sensor signal are used in combination to provide control information.

21. The user interface module of claim 20, wherein said user interface layer, said touch sensor layer and said piezoelectric layer are parts of a user interface module.

22. The user interface module of claim 20, wherein said touch sensor layer comprises a touch sensor for providing said sensor signal and said touch sensor is a capacitive sensor, a resistive-capacitive sensor or a resistive sensor.

23. The user interface module of claim 20, wherein said touch sensor layer is an impedance sensor conductive layer of a rectangular shape with four contact points at corners of said touch sensor.

24. The user interface module of claim 13, wherein said piezoelectric layer is made of a polymer or a polymer and ceramic mixture.

25. The user interface module of claim 13, further comprising:
a semi-soft polymer layer configured to provide a pre-selected bending level of said piezoelectric layer.

26. A method, comprising:
pressing a touch surface of a user interface layer by an object with a pressing force for applying a mechanical stress to a piezoelectric layer; and
providing a force detection signal in response to said object touching said touch surface with the pressing force by said piezoelectric layer, wherein said piezoelectric layer is configured to provide one or more levels of the force detection signal in response to said object touching said touch surface with one or more levels of said pressing force, wherein said one or more levels of the force detection signal correspond to said one or more levels of said pressing force and are for communicating at least two predetermined commands to an electronic device.

27. The method of claim 26, wherein said pressing is for providing said force detection signal to wake up said electronic device.

28. The method of claim 26, further comprising:
further touching a touch surface of the user interface layer by said object; and
providing by a touch sensor layer a sensor signal as a function of a location of the object on said touch surface in response to said further touching,
wherein said force detection signal and said sensor signal are used in combination to provide control information to an electronic device.

29. The method of claim 28, wherein said user interface layer, said touch sensor layer and said piezoelectric layer are parts of a user interface module.

30. The method of claim 28, wherein said touch sensor layer comprises a touch sensor for providing said sensor signal and said touch sensor is a capacitive sensor, a resistive-capacitive sensor or a resistive sensor.

31. The method of claim 28, wherein said touch sensor layer is an impedance sensor conductive layer of a rectangular shape with four contact points at corners of said touch sensor.

32. The method of claim 26, wherein the level of said force detection signal is proportional to said level of a predetermined force.

33. The method of claim 26, wherein said one or more predetermined commands are for continuously scrolling information using varying said force detection signal as a function of said pressing force.

34. The method of claim 26, wherein said piezoelectric layer is made of a polymer or a polymer and ceramic mixture.
